(19) United States
(12) Patent Application Publication
(10) Pub. No.: US 2005/0257957 A1
(43) Pub. Date: Nov. 24, 2005

(54) Printed wiring board with conductive constraining core including resin filled channels

(76) Inventor: Kaluk Vasoya, Huntington Beach, CA (US)

Correspondence Address: CHRISTIE, PARKER & HALE, LLP, PO BOX 7068, PASADENA, CA, 91109-7068, US

(21) Appl. No.: 11/131,130

(22) Filed: May 16, 2005

Related U.S. Application Data
(60) Provisional application No. 60/571,284, filed on May 15, 2004.
(60) Provisional application No. 60/604,857, filed on Aug. 27, 2004.
(60) Provisional application No. 60/653,258, filed on Feb. 15, 2005.
(60) Provisional application No. 60/662,162, filed on Mar. 15, 2005.

(51) Int. Cl. H05K 1/16; H05K 1/11

(52) U.S. Cl. 174/260; 174/262; 29/847; 29/852

(57) ABSTRACT

Printed wiring boards and methods of manufacturing printed wiring boards are disclosed. In one aspect of the invention, the printed wiring boards include electrically conductive constraining cores having at least one resin filled channel. The resin filled channels perform a variety of functions that can be associated with electrical isolation and increased manufacturing yields.

### CROSS-REFERENCE TO RELATED APPLICATION(S)

This application claims the benefit of U.S. Provisional Patent Application No. 60/571,284, filed May 15, 2004, U.S. Provisional Patent Application No. 60/604,857, filed Aug. 27, 2004, U.S. Provisional Application No. 60/653,258, filed Feb. 15, 2005, and U.S. Provisional Application No. 60/662,162, filed Mar. 15, 2005, which are hereby incorporated by reference in their entirety.

### FIELD OF THE INVENTION

The present invention relates generally to printed wiring boards and their manufacture and more specifically to printed wiring boards including electrically conductive constraining cores.

### BACKGROUND OF THE INVENTION

Considerable advances have been made in constructing thermally managed printed wiring boards. A particularly promising technology is the incorporation of carbon layers into printed wiring boards. Carbon layers can be used to lower the coefficient of thermal expansion of the printed wiring board and to improve the heat transfer characteristics of the printed wiring board. Various printed wiring boards including carbon layers are described in U.S. Pat. No. 4,318,954 to Jensen, U.S. Pat. No. 4,591,659 Leibowitz, U.S. Pat. No. 4,689,110 to Leibowitz, U.S. Pat. No. 4,812,792 to Leibowitz, U.S. Pat. No. 4,888,247 to Zweben et al., U.S. Pat. No. 6,013,588 to Ozaki, U.S. Pat. No. 6,869,664 to Vasoya et al. and U.S. Provisional Patent Application No. 60/604,857 entitled “Printed wiring boards possessing regions with different coefficients of thermal expansion” filed Aug. 27, 2004 to Vasoya. Each of these references is incorporated herein by reference in its entirety.

In addition to utilizing carbon layers to improve the thermal properties of a PWB, U.S. Pat. No. 6,869,664 to Vasoya et al. teaches that a printed wiring board can be constructed that uses carbon layers as functional layers. A functional layer is a layer that forms part of the circuit of the printed wiring board. U.S. Provisional Patent Application No. 60/604,857 entitled “Printed wiring boards possessing regions with different coefficients of thermal expansion” filed Aug. 27, 2004 to Vasoya also teaches replacing regions of the carbon layers with insert materials to create localized regions possessing physical characteristics distinct from other regions of the printed wiring board.

### SUMMARY OF THE INVENTION

Embodiments of the present invention use resin filled channels to electrically isolate regions of electrically conductive constraining cores. In one aspect of the invention, resin filled channels are used to electrically isolate plated through holes from the electrically conductive constraining core. In another aspect of the invention, resin filled channels can be used to create a split plane. In a further aspect of the invention, resin filled channels can electrically isolate lengths along exposed edges of the electrically conductive constraining core.

One embodiment of the invention includes an electrically conductive constraining core including a resin filled channel. Another embodiment of the invention includes an electrically conductive constraining core including a channel filled with a material having a dielectric constant less than or equal to 6.0 at 1 MHz. A further embodiment of the invention also includes a plurality of plated through holes. At least two of the plurality of plated through holes pass through the resin filled channel.

In another embodiment again, the electrically conductive constraining core includes an edge and the resin filled channel electrically isolates the electrically conductive constraining core from objects that only contact the electrically conductive constraining core at points along the length of the edge.

In a still further embodiment, the channel divides the electrically conductive constraining core into electrically isolated regions.

In yet another embodiment the channel defines a region within the electrically conductive constraining core and the materials of the region defined by the channel have physical properties that differ from at least one other region of the electrically conductive constraining core.

An embodiment of the method of the invention includes forming an electrically conductive constraining core base material, forming at least one channel in the electrically conductive constraining core base material, laminating a stack-up including the electrically conductive constraining core base material to enable resin to flow into the at least one channel, drilling holes through the laminated stack-up and plating the linings of the drilled holes with electrically conductive material.

In a further embodiment of the method of the invention, at least one channel is formed in a location such that at least two of the drilled holes extend through the channel.

In another embodiment of the method of the invention, at least one channel is formed in a location such that at least a length of an edge of the electrically conductive constraining core base material is electrically isolated from objects that only contact the laminated stack-up at locations along the length of the edge.

In a still further embodiment of the method of the invention, at least one channel is located to electrically isolate one portion of the electrically conductive constraining core base material and another portion.

Another embodiment again of the method of the invention includes obtaining Gerber data, generating drill data, generating pre-fab data for an electrically conductive constraining core, where the drill data includes at least one channel and generating artwork for an electrically conductive constraining core.

Another further embodiment of the method of the invention includes drilling a number of clearance holes in an electrically conductive constraining core that is greater than a predetermined number of plated through holes that are electrically isolated from the electrically conductive constraining core.

Another additional embodiment of the invention also includes laminating a stack-up including the clearance hole drilled electrically conductive constraining core and drilling the plated through holes that are electrically isolated from the electrically conductive constraining core through the laminated stack-up.

Another further additional embodiment of the method of the invention also includes drilling plated through holes that are electrically connected to the electrically conductive constraining core.

### BRIEF DESCRIPTION OF THE DRAWINGS

FIG. 1 is a schematic cross section of a printed wiring board constructed in accordance with an embodiment of the present invention that includes two electrically conductive constraining cores;

FIG. 2a is an embodiment of an electrically conductive constraining core in accordance with an embodiment of the present invention that is clad on both sides;

FIG. 2b is another embodiment of an electrically conductive constraining core that is not clad;

FIG. 2c is a further embodiment of an electrically conductive constraining core that is clad one side;

FIG. 3 is a flow chart showing a process for constructing a printed wiring board in accordance with an embodiment of the method of the present invention;

FIG. 4 is a flow chart illustrating a process for drilling tooling holes in accordance with an embodiment of the method of the invention;

FIG. 5 is an isotropic view of a panel that includes tooling holes in accordance with an embodiment of the present invention;

FIG. 6a is a schematic top view of a pair of plated through holes in a printed wiring board in accordance with an embodiment of the present invention;

FIG. 6b is a schematic top view of a pair of clearance holes drilled in an electrically conductive constraining core;

FIG. 6c is a schematic cross-section view of a laminated stack-up showing resin filled clearance holes in an electrically conductive constraining core;

FIG. 6d is a schematic cross-section view of a laminated stack-up showing a pair of holes drilled through resin filled clearance holes in an electrically conductive constraining core;

FIG. 7a is a schematic top view of a pair of plated through holes in a printed wiring board in accordance with an embodiment of the present invention;

FIG. 7b is a schematic top view of a channel drilled in an electrically conductive constraining core;

FIG. 7c is a schematic cross-section view of a laminated stack-up showing a resin filled channel in an electrically conductive constraining core;

FIG. 7d is a schematic cross-section view of a laminated stack-up showing a pair of holes drilled through a resin filled channel in an electrically conductive constraining core;

FIG. 8a is a schematic top view of a pair of plated through holes in a printed wiring board in accordance with an embodiment of the present invention;

FIG. 8b is a schematic top view of a channel slot drilled in an electrically conductive constraining core;

FIG. 8c is a schematic cross-section view of a laminated stack-up showing a resin filled channel in an electrically conductive constraining core;

FIG. 8d is a schematic cross-section view of a laminated stack-up showing a pair of holes drilled through a resin filled channel in an electrically conductive constraining core;

FIG. 9a is a schematic top view of a pair of plated through holes in a printed wiring board in accordance with an embodiment of the present invention;

FIG. 9b is a schematic top view of a pair of clearance holes drilled in an electrically conductive constraining core that are located very close to each other;

FIG. 9c is a schematic cross-section view of a laminated stack-up showing resin filled clearance holes in an electrically conductive constraining core;

FIG. 9d is a schematic cross-section view of a laminated stack-up showing a pair of holes drilled through resin filled clearance holes in an electrically conductive constraining core;

FIG. 10a is a schematic top view of a pair of plated through holes in a printed wiring board in accordance with an embodiment of the present invention;

FIG. 10b is a schematic top view of a channel drilled in an electrically conductive constraining core;

FIG. 10c is a schematic cross-section view of a laminated stack-up showing a resin filled channel in an electrically conductive constraining core;

FIG. 10d is a schematic cross-section view of a laminated stack-up showing a pair of holes drilled through a resin filled channel in an electrically conductive constraining core;

FIG. 11a is a schematic top view of a pair of plated through holes in a printed wiring board in accordance with an embodiment of the present invention;

FIG. 11b is a schematic top view of a channel slot drilled in an electrically conductive constraining core;

FIG. 11c is a schematic cross-section view of a laminated stack-up showing a resin filled channel in an electrically conductive constraining core;

FIG. 11d is a schematic cross-section view of a laminated stack-up showing a pair of holes drilled through a resin filled channel in an electrically conductive constraining core;

FIG. 12a is a schematic cross-section view of a printed wiring board in accordance with the present invention showing an electrically conductive constraining core that is divided into a split plane and that is electrically isolated at two edges;

FIG. 12b is a schematic top view of a panel of an electrically conductive constraining core base material during manufacture showing the location of channels routed in the panel;

FIG. 13a is a schematic cross-section view of a printed wiring board in accordance with the present invention showing an electrically conductive constraining core in which a region has been cut out;

FIG. 13b is a schematic top view of a panel of an electrically conductive constraining core base material during manufacture showing the location of channels routed in the panel in preparation for the cut out of a region;

FIG. 14a is a schematic cross-section view of a printed wiring board in accordance with the present invention showing an electrically conductive constraining core in which there is a region possessing localized physical characteristics;

FIG. 14b is a schematic top view of a panel of an electrically conductive constraining core base material during manufacture showing the location of channels routed in the panel in preparation for the cut out of a region;

FIG. 14c is a schematic top view of a panel of an electrically conductive constraining core base material in which an insert material is placed in a cut out region;

FIG. 15 is a flow chart showing a process for generating drill data, artwork and pre-fab data for at least one electrically conductive constraining core using Gerber data in accordance with the present invention;

FIG. 16a is a graphical representation of artwork in Gerber data for a split plane;

FIG. 16b is a graphical representation of the locations in which plated through holes will be drilled to implement the split plane shown in FIG. 16a;

FIG. 16c is a graphical representation of clearance hole drill data generated from FIGS. 16a and 16b;

FIG. 16d is a graphical representation of the modifications to the drill data shown in FIG. 16c involving replacing clearance holes with slot drilled channels in accordance with an embodiment of the method of the present invention;

FIG. 16e is a graphical representation of pre-fab data including additional routed channels associated with the electrical isolation of electrically conductive constraining core that is generated in accordance with an embodiment of the present invention using the artwork shown in FIG. 16a;

FIG. 16f is a graphical representation of artwork generated from the drill data shown in FIG. 16e in accordance with an embodiment of the method of the present invention; and

FIG. 16g is a schematic top view of an electrically conductive constraining core panel that can be used to manufacture a number of electrically conductive constraining core printed wiring boards in accordance with an embodiment of the method of the invention.

### DETAILED DESCRIPTION OF THE INVENTION

Turning now to the drawings, embodiments of printed wiring boards and methods of constructing printed wiring boards are shown. In many embodiments, the printed wiring boards include electrically conductive constraining cores. The manner in which the electrically conductive constraining cores are processed, in many instances, reduces the possibility that unwanted electrical connections will occur within the board and between the board and external devices. In several embodiments, the printed wiring boards include plated through holes that are electrically isolated from the conductive constraining cores by continuous channels of dielectric material. In several embodiments, the channels are formed by drilling multiple holes in a manner that results in a continuous channel. In other embodiments, a routing tool is used to create a channel by routing a slot in the electrically conductive constraining core. In each instance the channel is filled by resin either through screening or reflow during lamination. In many embodiments, routing tools are used to create split planes and to electrically isolate lengths along the edges of the electrically conductive constraining cores. In addition, processes for increasing yield during manufacture are also discussed.

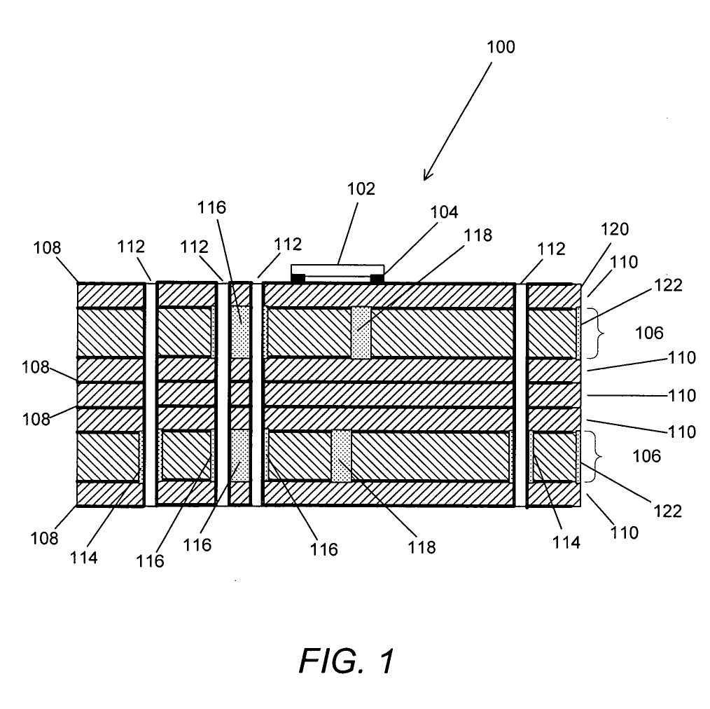

A printed wiring board in accordance with an embodiment of the present invention is shown in FIG. 1. The printed wiring board 100 is constructed from layers of different materials and has an electronic device 102 mounted to it via interconnection components 104. The various layers used to construct the printed wiring board include two electrically conductive constraining cores 106, layers of metal or other electrically conductive material 108 and layers of dielectric material 110. The layers of dielectric material are arranged between the layers of metal and the electrically conductive constraining cores to inhibit unwanted electrical connections.

Desired electrical connections are established between the layers using plated through holes 112 or vias. In many embodiments (including the illustrated embodiment), the electrically conductive constraining cores 106 act as functional layers within the printed wiring board. Unless the plated through holes are electrically isolated from the electrically conductive constraining cores, an electrical connection can be created between the electrically conductive constraining core and the plated through hole.

Many of the plated through holes are not electrically connected to one or both of the electrically conductive constraining cores. In several instances, plated through holes are electrically isolated from one (or both) of the electrically conductive constraining cores by resin filled clearance holes 114. In other instances, several plated through holes are electrically isolated from an electrically conductive constraining core by a resin filled channel 116 within the electrically conductive constraining core.

In the illustrated embodiment, resin filled channels 118 extend from one side of the board to the other. As discussed above, the electrically conductive constraining cores of the illustrated printed wiring board 100 are functional layers. In particular, they form split ground and power planes. The resin filled channels 118 serve to electrically isolate one side of the split plane from the other.

An additional feature of the illustrated embodiment is that the right hand edge 120 of the printed wiring board is electrically isolated. The layers of metal or an electrically conductive material 108 do not extend all the way to the right hand edge 120 of the printed wiring board 100 and a barrier of dielectric material 122 is interposed between the electrically conductive constraining cores and the edge 120 of the printed wiring board, which inhibits unwanted electrical connections between an electrically conductive constraining core and an object contacting the right hand edge 120 of the printed wiring board.

In one embodiment, the layers of dielectric material can be constructed from any dielectric material that can be used in the construction of a printed wiring board. Many examples of suitable materials are disclosed in U.S. Pat. No. 6,869,664 to Vasoya et al. Similarly, the layers of metal or other electrically conductive material can be constructed from any electrically conductive material that can be used in the construction of a printed wiring board. In several embodiments, the metal used is copper. Other examples of suitable materials are also provided in U.S. Pat. No. 6,869,664 to Vasoya et al.

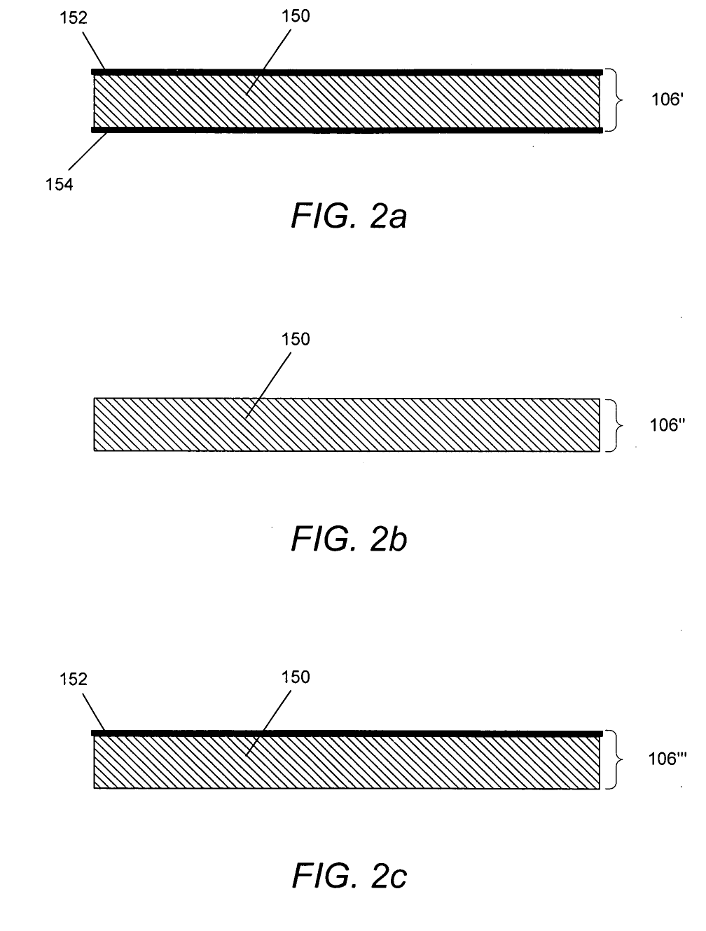

Electrically conductive constraining cores in accordance with embodiments of the present invention can be constructed in a variety of ways. A number of embodiments of electrically conductive constraining cores are illustrated in FIGS. 2a-2c. However, any of the combinations of materials used to construct electrically conductive constraining cores taught in the references identified above (see Background) can be used to construct electrically conductive constraining cores in accordance with the present invention.

A cross-sectional view of an embodiment of an electrically conductive constraining core in accordance with the present invention is shown in FIG. 2a. The electrically conductive constraining core 106′ includes a layer of electrically conductive material 150 sandwiched between a first layer of metal or other electrically conductive material 152 and a second layer of metal or other electrically conductive material 154. The electrically conductive constraining cores shown in FIGS. 2b and 2c are similar with the exception that the electrically conductive constraining core 106″ shown in FIG. 2b is not clad with layers of metal and the electrically conductive constraining core 106′″ shown in FIG. 2c is only clad on one side.

In one embodiment, the layer of electrically conductive material 150 can be constructed using fibrous material impregnated with resin. The fibrous material can be carbon, graphite fibers such as CNG-90, CN-80, CN-60, CN-50, YS-90, YS-80, YS-60 and YS-50 manufactured by Nippon Graphite Fiber of Japan, K63B12, K13C2U, K13C1U, K13D2U, K13A1L manufactured by Mitsubishi Chemical Inc. of Japan or T300-3k, T300-1k manufactured by Cytec Carbon Fibers LLC of Greenville, S.C. In other embodiments, the fibrous material can be metal coated and impregnated with resin. Examples of fibers that can be coated with metal include carbon, graphite, E-glass, S-glass, Aramid, Kevlar, quartz or any combination of these fibers. In another embodiments, the layer of electrically conductive material 150 can be constructed using C-SiC (Carbon-Silicon Carbide) manufactured by Starfire Systems Inc. of Malta, N.Y. The configurations in which the fibrous materials can be arranged include being woven, unidirectional or non-woven mats. In several embodiments, the woven material can be in the form of a Plain weave, Twill weave, 2×2 twill, Basket weave, Leno weave, Satin weave, stitched uni weave or 3D (Three dimensional) weave. In several embodiments, non-woven material can be in the form of Uni-tape or a mat. In many embodiments, carbon mats such as grade number 8000040 or 8000047, 2 oz and 3 oz respectively manufactured by Advanced Fiber NonWovens, East Walpole, Mass. are used in the construction of electrically conductive constraining cores. The fibers can be continuous or discontinuous. In embodiments where discontinuous fibers are used, the fibers can be spin broken or stretch broken fibers such as part no. X0219 manufactured by Toho Carbon Fibers Inc. of Rockwood, Tenn. In other embodiments, any combination of fibrous material and resin can be used that results in the electrically conductive constraining core possessing a dielectric constant greater than 6.0 at 1 MHz. In other embodiments, the electrically conductive constraining core possesses a dielectric constant greater than 10.0 at 1 MHz.

In other embodiments, the layer of electrically conductive material 150 can be constructed from PAN, Pitch or a combination of both fibers. In further embodiments, the layer of electrically conductive material 150 can be constructed from a solid carbon plate. In one embodiment, a carbon plate can be made using compressed carbon powder. In other embodiments, a carbon plate can be made using carbon flakes or chopped carbon fiber.

In another embodiment, layer of electrically conductive material is not limited to a carbon composite. Any material that can result dielectric constant of conductive constraining core greater than 6.0 at 1 MHz and requires inventive method described later in the description to construct conductive constraining core can be used.

In one embodiment, the resin used to construct the layer of electrically conductive material 150 can be an Epoxy based resin, Phenolic based resin a Bismaleimide Triazine epoxy (BT) based resin, a Cynate Ester based resin and/or a Polyimide based resin. In other embodiments, the resin includes fillers such as pyrolytic carbon powder, carbon powder, carbon particles, diamond powder, boron nitride, aluminum oxide, ceramic particles, and phenolic particles to improve the electrical and/or physical properties of the layer of electrically conductive material 150. In other embodiments, resins including any electrically conductive resin can be used in the construction of a layer of electrically conductive material 150.

As can be understood from the materials described above, the layer of electrically conductive material can derive the property of electrical conductivity from a substrate or reinforcing material used to construct the layer and/or a resin used in the construction of the layer. The choice of materials for use in the construction of the layer of electrically conductive material typically depends on the heat transfer, coefficient of thermal expansion and stiffness desired from the completed printed wiring board.

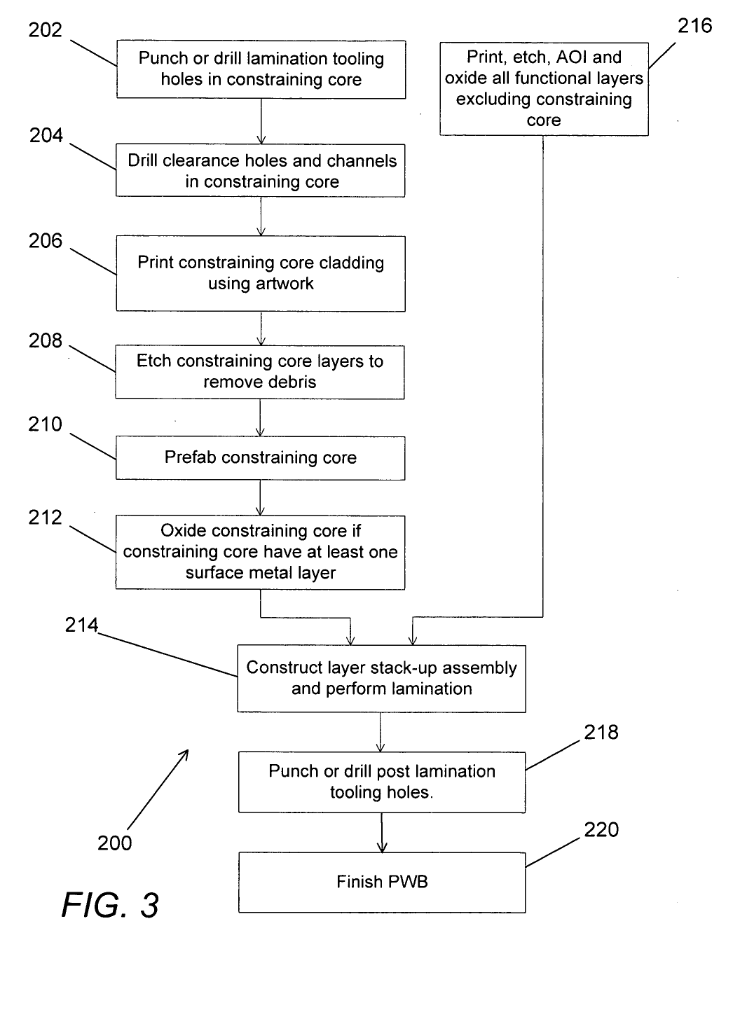

A process for constructing printed wiring boards in accordance with the method of the invention is illustrated in FIG. 3. The process (200) includes punching or drilling (202) lamination tooling holes in the electrically conductive constraining core(s). The process also includes drilling (204) clearance holes and channels in the electrically conductive constraining core(s). Any layers of electrically conductive material on the surfaces of the electrically conductive constraining core can be patterned. In the illustrated embodiment, the patterning is performed by printing (206) and etching (208) of the constraining core(s) using appropriate artwork. The constraining core(s) can undergo (210) prefab processing, which involves the creation of channels within the printed wiring board that are filled with resin during subsequent lamination. Prior to manufacture of a completed printed wiring board, constraining core(s) that include metal cladding are oxided (212).

In order to complete the printed wiring board, a layer stack-up assembly is created (214) using the electrically conductive constraining core(s) and other prepregs and/or laminates that have been patterned (216) to implement the other functional layers of the printed wiring board. The layer stack-up assembly is laminated (214) and post lamination tooling holes are punched or drilled (218) in the laminated stack-up assembly. The printed wiring board can then be finished (220).

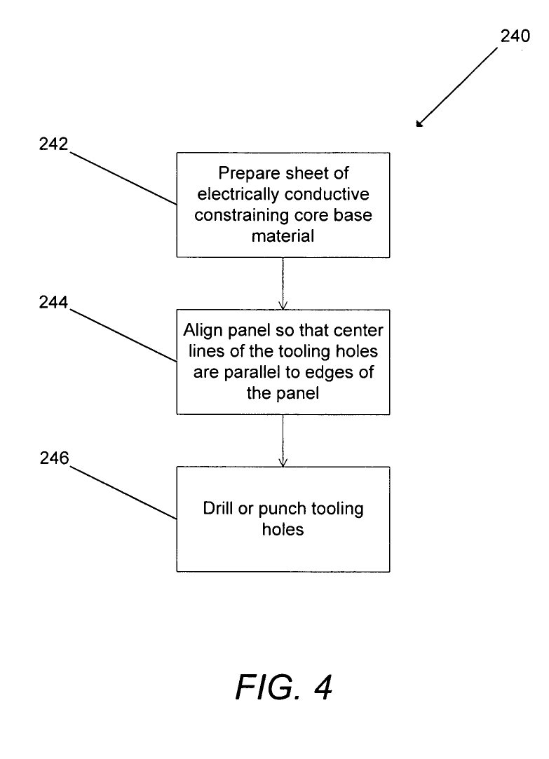

A process for drilling tooling holes in a constraining core in accordance with an embodiment of the method of the invention is illustrated in FIG. 4. The process 240 involves preparing (242) a sheet of electrically conductive constraining core base material to form a panel. The panel is then aligned (244) so that tooling holes can be cut, punched or drilled into the panel. Typically, the alignment ensures that the center lines of the tooling holes are parallel to the edges of the panel.

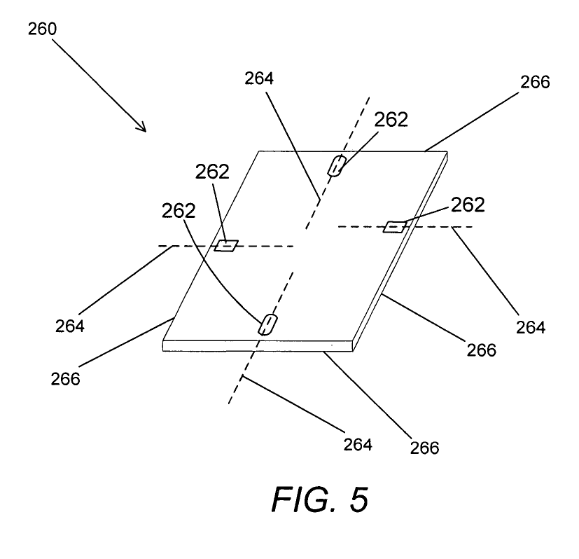

In embodiments where the electrically conductive constraining core includes a woven material such as woven carbon fiber, precise alignment of the tooling holes with the edges of the panels can provide precise alignment between the tooling holes and the direction of the weave of the fibers. Precise alignment of the direction of the weave of the fibers can be useful in preventing warping when multiple electrically conductive constraining cores are combined to form a printed wiring board in accordance with the method of the present invention. Once the panel has been aligned, the tooling holes can be created (246). A panel 260 including tooling holes 262 is illustrated in FIG. 5. The center lines 264 of the tooling holes are aligned with the edges of the panels 266.

Referring back to FIG. 1, a number of the plated through holes are electrically isolated from one or both of the electrically conductive constraining cores by resin filled clearance holes. The electrical isolation is achieved, because the resin is a poor conductor of electricity. Typically, resins used to fill clearance holes in accordance with the present invention have a dielectric constant less than or equal to 6.0 at 1 MHz. A resin filled clearance hole can be created by drilling a hole having a greater diameter than the plated through hole that it is intended to isolate through the electrically conductive constraining core. The drilled hole fills with resin during lamination and a hole that is drilled through the resin filled clearance hole is electrically isolated from the electrically conductive constraining core.

Once tooling holes have been created, the electrically conductive constraining core can be drilled with clearance holes. If electrically conductive particles become trapped within the resin inside a clearance hole, a potential exists for the electrically conductive particle to create an electrical path between a plated through hole and the electrically conductive constraining core. Reducing stray electrically conductive particles during manufacture can result in increased production yields. The following discussion addresses ways in which clearance holes can be replaced by channels in order to reduce the likelihood that debris will cause unwanted electrical connections.

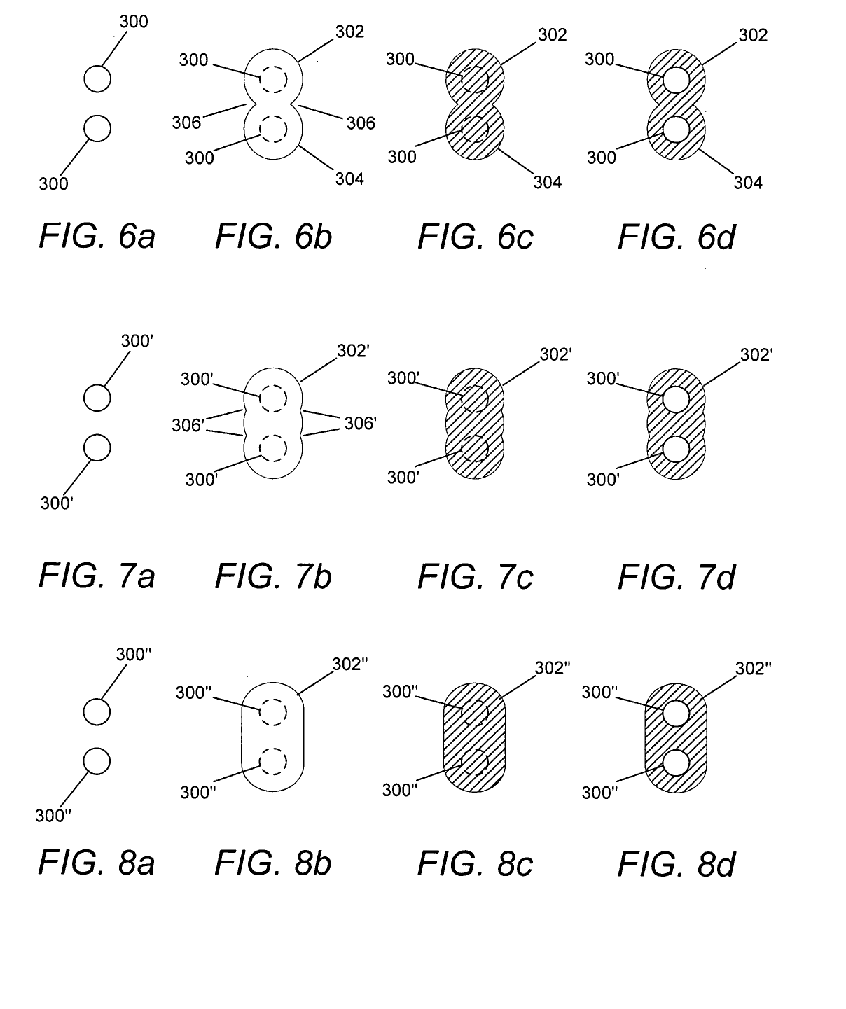

Often, a number of plated through holes are located close to each other. A pair of plated through holes 300 that are located close to each other in a printed wiring board that includes an electrically conductive constraining core are shown in FIG. 6a. The plated through holes are electrically isolated from the electrically conductive constraining core.

A printed wiring board that includes the two plated through holes shown in FIG. 6a can be constructed by drilling two clearance holes in an electrically conductive constraining core base material. The locations of the centers of each of the clearance holes corresponds to the locations of the centers of each of the plated through holes. As discussed above, the diameter of a clearance hole is greater than the diameter of the plated through hole that it is intended to isolate. The locations of the two clearance holes in the electrically conductive constraining core are shown in FIG. 6b. The location of a first clearance hole 302 and a second clearance hole 304 are illustrated. The intended location of the plated through holes is indicated via ghost lines 300. In the illustrated embodiment, the first clearance hole 302 overlaps with the second clearance hole 304. The portions 306 of the electrically conductive constraining core base material that protrude into the space created by the drilling of the clearance holes are susceptible to breaking off during lamination.

The electrically conductive constraining core base material can be laminated with other materials to form a printed wiring board. Following lamination, the space created by the drilling of clearance holes is filled with resin. The resin filled clearance holes are illustrated in FIG. 6c. The plated through holes shown in FIG. 6a can be completed by drilling holes through the resin filled clearance holes and then plating the holes. Holes drilled through the resin filled clearance holes are illustrated in FIG. 6d.

As discussed above, the portions 306 of the electrically conductive constraining core that protrude into the space created by the drilling of the clearance holes are susceptible to breaking off. If a portion breaks off and is suspended within the resin filling a clearance hole, the portion could create an unintended electrical connection between one of the plated through holes and the electrically conductive constraining layer. The likelihood that a portion of the electrically conductive constraining core breaks off and creates an unwanted electrical connection within a printed wiring board can be reduced in accordance with the method of the present invention by using resin filled channels to isolate groups of plated through holes from the electrically conductive constraining core.

An embodiment of a process in accordance with the present invention for constructing a resin filled channel can be understood with reference to FIGS. 7a-7d. A pair of plated through holes similar to the plated through holes 300 illustrated in FIG. 6a are illustrated in FIG. 7a. The plated through holes 300′ shown in FIG. 7a pass through an electrically conductive constraining core located within the printed wiring board and are electrically isolated from the electrically conductive constraining core. In order to manufacture the printed wiring board including the plated through holes shown in FIG. 7a, a channel can be cut in the electrically conductive constraining core base material. A channel cut in an electrically conductive constraining core base material is shown in FIG. 7b. The channel is created by drilling a number of holes greater than the number of plated through holes in the electrically conductive constraining core base material. The holes can be created using end mills or slot drill bits. In the illustrated embodiment, three holes 302′ are drilled in a line. The intended locations 300′ of the plated through holes are shown in ghost lines. The portions 306′ of the electrically conductive constraining core that protrude into the channel are considerably less pronounced than the portions 306 shown in FIG. 6b. Although three holes are shown in FIG. 6b, in other embodiments a greater number of holes can be used to further smooth the edges of the channel. In addition, the holes need not be located along a straight line and none of the holes need correspond with the location of the clearance holes shown in FIG. 6b. The filling of the channel with resin and the drilling and plating of holes through the resin filled channel are shown in FIGS. 7c and 7d.

Another process for creating a resin filled channel in accordance with an embodiment of the method of the invention can be understood with reference to FIGS. 8a-8d. As with FIGS. 6a and 7a, FIG. 8a shows a pair of plated through holes that extend through a printed wiring board that includes an electrically conductive constraining core, from which the plated through holes are isolated. As with FIG. 7b, a channel is created in the electrically conductive constraining core by removing at least a portion of the material that would remain had clearance holes been drilled. Almost all of the material shown as 306 in FIG. 6a can be removed by using a slot drill to drill a slot in the electrically conductive constraining core. An embodiment of a slot 302″ in accordance with the present invention is shown in FIG. 8b. The filling of the slot with resin and the drilling and plating of holes through the resin filled slot are shown in FIGS. 8c and 8d.

In several embodiments, clearance holes that overlap to a very significant degree can be left as clearance holes due to the minimal amount of protruding material remaining after the drilling of the holes. For example, when the holes have a diameter of 25 mil substitution with a channel is not required when the distance between the centers of the two adjacent clearance holes is less than 20 mil. In other embodiments, substitution is ignored when the distance between the centers of 25 mil clearance holes is less than 15 mil.

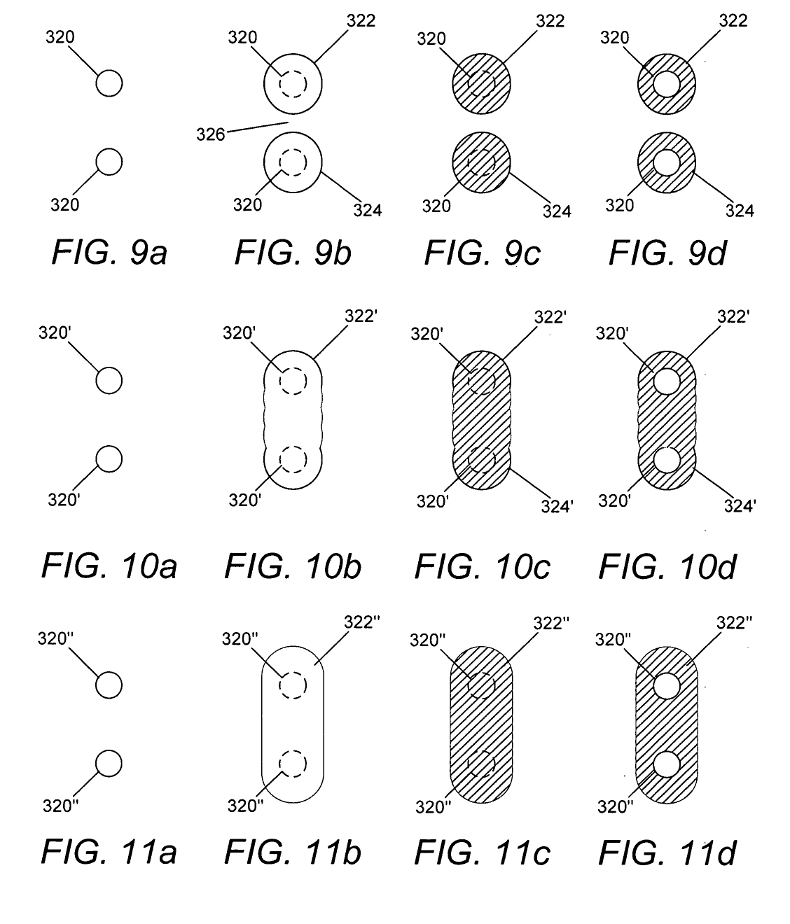

The above discussion deals with the case where two plated through holes are located close enough that any clearance holes associated with them would be very close to each other. A pair of plated through holes are illustrated in FIG. 9a. The plated through holes 320 extend through a printed wiring board including at least one electrically conductive constraining core. A printed wiring board including the plated through holes shown in FIG. 9a can be constructed by drilling clearance holes in an electrically conductive constraining core base material. The location of a first clearance hole 322 and a second clearance hole 324 in an electrically conductive constraining core is shown in FIG. 9b. The intended location 320 of the plated through holes is indicated with ghost lines. A region 326 of the electrically conductive material exists between the two drilled clearance holes. Pressures during lamination can result in electrically conductive material breaking from this region. The filling of the clearance holes with resin is shown in FIG. 9c and the drilling and plating of holes through the clearance holes is shown in FIG. 9d.

The potential for portions of material to break away from the electrically conductive constraining core in the region 326 increases the likelihood that unwanted electrical connections will exist in a completed printed wiring board. As an alternative, plated through holes can be electrically isolated from an electrically conductive constraining core using a resin filled channel instead of clearance holes. As discussed above, a channel is created by drilling additional holes or using a routing tool with the result that at least some of the material that would have remained had clearance holes been drilled is removed. A process in accordance with an embodiment of the method of the invention for creating a channel by drilling additional holes in an electrically conductive constraining core base material can be understood with reference to FIGS. 10a-10d. The holes 322′ shown in FIG. 10b do not result in a region similar to the region 326 shown in FIG. 9a.

The creation of a channel to eliminate the region 326 by using a slot drill to create a slot in an electrically conductive constraining core base material is illustrated in FIGS. 11a-11d. As with the creation of a channel by drilling additional holes, FIG. 11b shows that the channel 322″ created using a slot drill does not include a region similar to the region 326 shown in FIG. 9a.

Once clearance holes and channels have been drilled in an electrically conductive constraining core, cladding on the electrically conductive constraining core can be printed and etched. Printing is performed by aligning the top and bottom masking artwork with the holes and channels drilled in the electrically conductive constraining core. The alignment can be simplified using tooling holes or registration targets. In several embodiments, the artwork is created with a view to using the etching process to remove debris from the channels in the electrically conductive constraining core. The high pressure of the etching chemicals can remove loose fibers from the channels and the chemicals can etch away any loose flecks of metal. In embodiments where the electrically conductive constraining core is not clad, high pressure water or air can be used to remove debris from the channels.

In many embodiments, the artwork covers drilled clearance holes that do not form part of a channel. Masking these holes increases the likelihood that the cladding material extends to the edges of the holes. When the electrically conductive constraining cores are inspected using X-rays to obtain registration as part of the process of drilling through holes, everything except the cladding material is typically transparent to the X-rays. Therefore, better registration of the location of the clearance holes can be obtained by preventing etching chemicals from etching the cladding material away from the edges of clearance holes.

Once the etching process is complete, pre-fab processes can be performed. The pre-fab processes involve creating long channels in the board. These channels can be created at the same time as the drilling of clearance holes and channels. However, the longer channels created in the printed wiring board during the pre-fab of the printed wiring board can significantly weaken it. Therefore, yields can be increased by performing the pre-fab process after etching. Typically, the channels are cut with a routing tool and the channels become filled with resin as a result of reflow during lamination. In other embodiments, liquid phase or powder resin is screened into the channels prior to lamination.

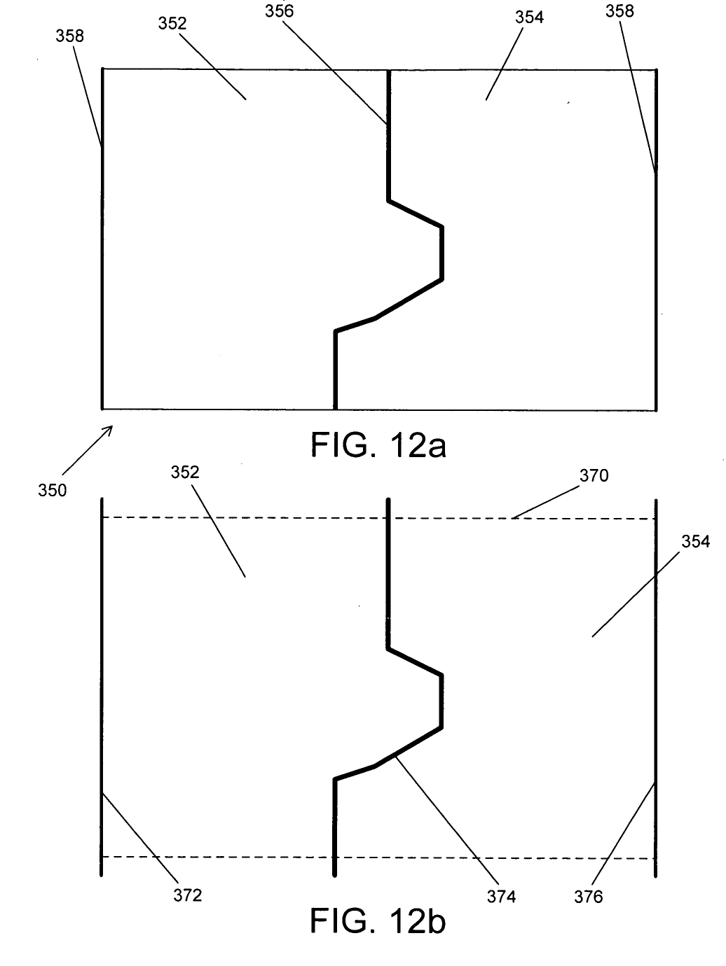

As discussed above, embodiments of printed wiring boards in accordance with the present invention can include electrically conductive constraining cores that are configured as combined power and ground planes and/or are constructed so that lengths from a small segment to an entire edge of the printed wiring board are electrically isolated. An electrically conductive constraining core configured as a split power and ground plane is illustrated in FIG. 12a. The electrically conductive constraining core is divided into a first region 352 and a second region 354 by a resin filled channel 356. Two of the edges of the electrically conductive constraining core are electrically isolated by strips of resin 358 running along the entire edge of the constraining core.

Prefab manufacturing processes that can be used to construct the electrically conductive constraining core shown in FIG. 12a can be understood with reference to FIG. 12b, which shows a panel of the base electrically conductive constraining core material in which three channels were routed during pre-fab. In many embodiments, one or more electrically conductive constraining cores are manufactured by drilling and routing a panel of suitable material and then punching individual electrically conductive constraining cores out of the panel. In FIG. 12b, the dimensions of the electrically conductive constraining core that is to be punched out of the panel are indicated by ghost lines 370. The first channel 372 is routed along an intended edge of the electrically conductive constraining core. The first channel 372 is longer than the intended edge of the electrically conductive constraining core to ensure that resin filing the channel can extend the entire length of the edge of the electrically conductive constraining core.

The second channel 374 is routed along a line that divides the first region 352 of the intended electrically conductive constraining core from the second region 354 of the intended electrically conductive constraining core. When the second channel is filled with resin and the electrically conductive constraining core is punched out of the panel, the second channel electrically isolates the first region from the second region. As with the first channel, the second channel extends beyond the boundaries of the intended electrically conductive constraining core to ensure that the entire length of the channel can be filled with resin. The third channel is similar to the first channel. When the third channel is filled with resin and the electrically conductive constraining core is punched out from the panel, the third channel electrically isolates a second edge of the electrically conductive constraining core. In instances where the electrically conductive constraining core is clad with at least one layer of metal or similar electrically conductive material, then electrical isolation requires that the metal or other material typically should not extend to the isolated edge of the electrically conductive constraining layer. This requirement can be achieved as part of the printing and etching processes described above.

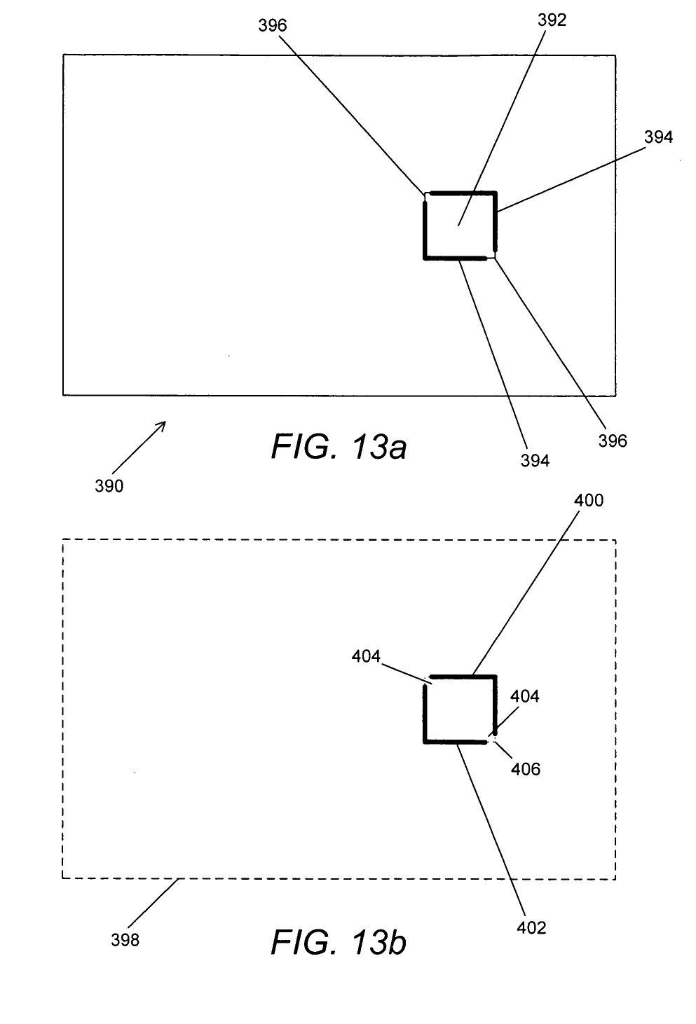

Many embodiments of printed wiring boards in accordance of the present invention include cut out regions. An example of such a printed wiring board in accordance with the present invention is shown in FIG. 13a. FIG. 13a illustrates an electrically conductive constraining core of a printed wiring board 390 that includes a cut out region 392. Regions 394 along the edges of the cut out are electrically isolated. In the illustrated embodiment, resin provides the electrical isolation.

Pre-fab processes that can be performed during the construction of an electrically conductive constraining core in accordance with an embodiment of the method of the present invention that is similar to the constraining core shown in FIG. 13a can by understood by referring to FIG. 13b. As discussed above, electrically conductive constraining cores are typically constructed from a panel of suitable material. Such a panel is illustrated in FIG. 13b. The intended boundary of the electrically conductive constraining core that will be punched out of the panel is illustrated using ghost lines 398. The cut out region is prepared by routing a first channel 400 and a second channel 402. The two channels form the regions that are electrically isolated. The gaps between the channels 404 provide stability during lamination, which enables resin to fill the channels. The cut out is completed by cutting along the ghost line 406.

The resin filled channels provide electrical isolation to at least a length of the electrically conductive constraining core. Following the completion of the cut out, lengths of edges of the electrically conductive constraining core that are not electrically isolated can be electrically isolated by applying an epoxy or any dielectric elastomer. In instances where the electrically conductive constraining core is clad with at least one layer of metal or similar electrically conductive material, then electrical isolation typically requires that the metal or other material should not extend to the isolated edge of the electrically conductive constraining layer. This requirement can be achieved as part of the printing and etching processes described above.

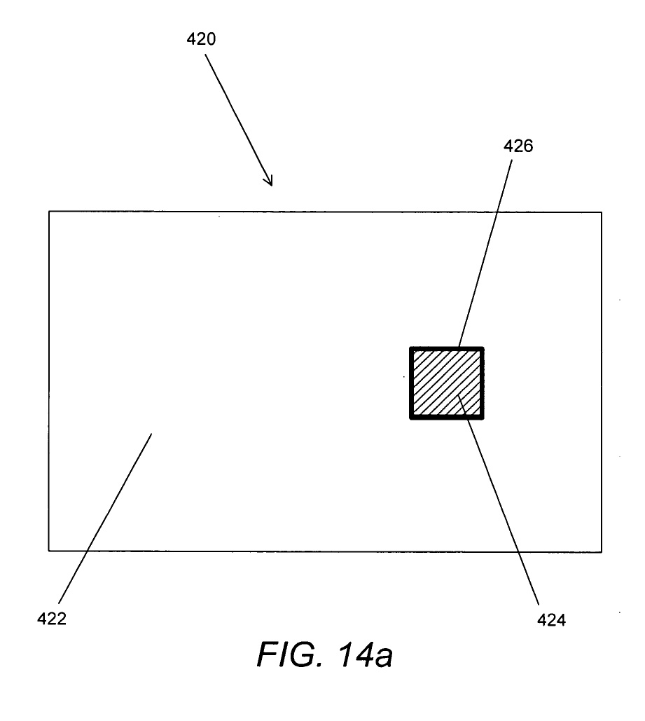

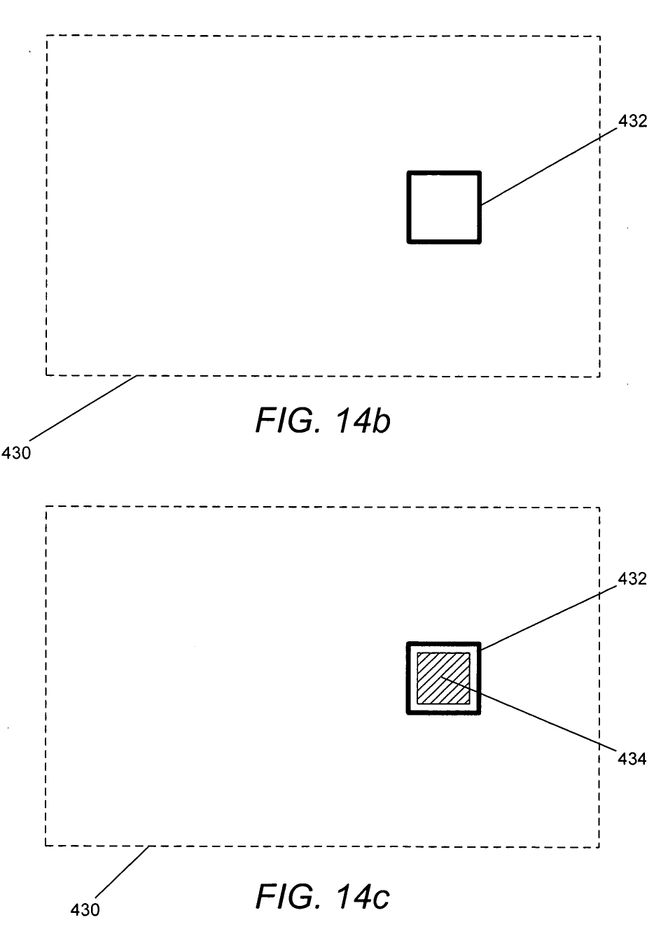

As discussed above, printed wiring boards in accordance with the present invention can be constructed with localized regions that possess distinct physical characteristics. An embodiment of an electrically conductive constraining core from a printed wiring board possessing regions with distinct coefficients of thermal expansion is illustrated in FIG. 14a. The electrically conductive constraining core 420 is constructed from a first material similar to any of the electrically conductive constraining core base materials described above and a second insert material possessing a coefficient of thermal expansion that is different to that of the electrically conductive constraining core base material. In other embodiments, the two materials possess other distinct physical properties. In several embodiments, the insert has the same coefficient of thermal expansion as the electrically conductive constraining core material. The electrically conductive constraining core material and the insert material are electrically isolated by a band of resin 424.

Pre-fab processes that can be used in the construction of an electrically conductive constraining core similar to the one shown in FIG. 14a in accordance with an embodiment of the method of the invention can be understood with reference to FIGS. 14b and 14c. As discussed above, electrically conductive constraining cores can be constructed from panels of suitable material. A panel that can be used to construct an electrically conductive constraining core is illustrated in FIG. 14b. The intended edges of the electrically conductive constraining core are shown by ghost lines 430. In order to accommodate a piece of insert material, a channel is created in the panel to remove an area of the electrically conductive constraining core material that is slightly larger than the insert material. A panel with an area removed to accommodate an insert material is shown in FIG. 14b. The insert material is then placed in the space created by the removal of the region of electrically conductive constraining core base material. A panel with a piece of insert material 434 appropriately placed in the space created by the removal of the electrically conductive constraining core material is shown in FIG. 14c. During lamination, resin flows into the gap between the electrically conductive constraining core base material and the insert material.

Once any pre-fab processing is completed, the electrically conductive constraining core is prepared for lamination. In several embodiments of the method of the present invention, clad electrically conductive constraining cores are prepared for lamination using oxide treatment. In embodiments where the electrically conductive constraining core is unclad, plasma treatment can be used to prepare the surfaces of the electrically conductive constraining core for bonding.

The other layers of the printed wiring board are prepared using processes typically used to prepare prepregs and laminates for lamination. The laminates are printed, etched and automatic optical inspection is performed as required. The other materials can also be subjected to oxide treatment as necessary. When all of the base materials are prepared for lamination, a layer stack-up assembly is created and lamination can be performed in accordance with the manufacturer recommended lamination cycles for each of the materials in the layer stack-up. Following lamination, post lamination registration targets are used to accurately align the board for the purpose of drilling post lamination tooling holes and the printed wiring board can be finished.

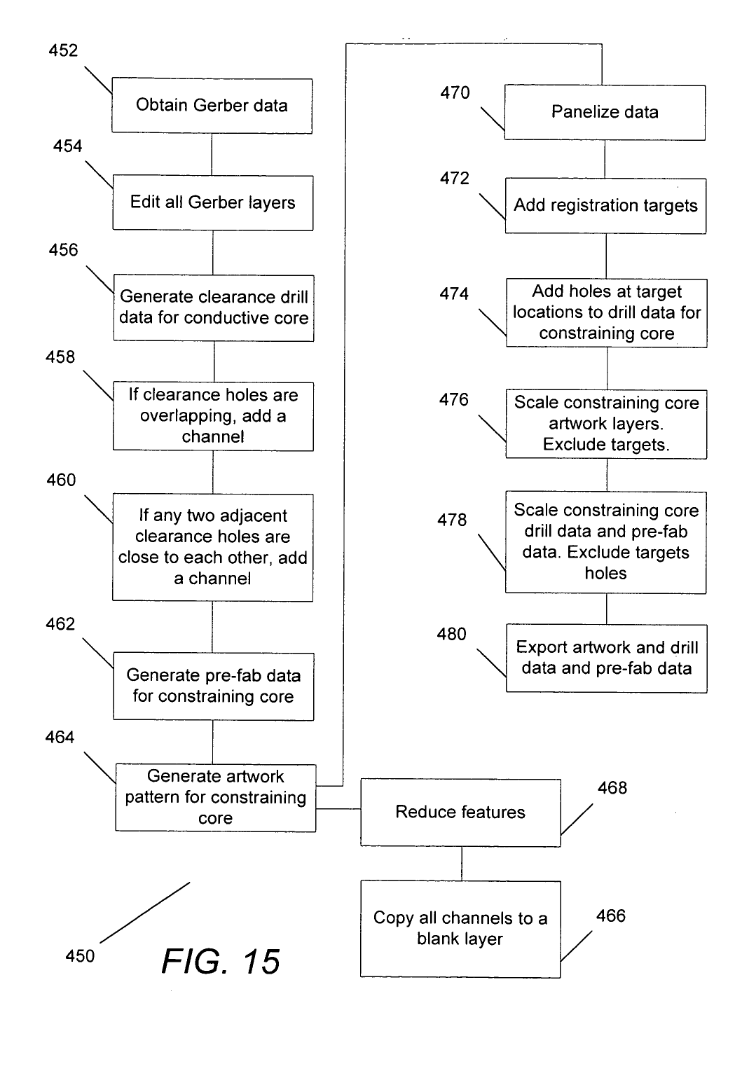

In order to construct a completed printed wiring board in accordance with the present invention, many to the techniques described above can be combined to accommodate electrically conductive constraining cores in the printed wiring board. In one embodiment of the method of the invention, an initial printed wiring board design is developed that does not accommodate the electrically conductive nature of any electrically conductive constraining cores within the printed wiring board. Such a design can be developed on any of a variety of commercially available CAM editing software packages such as Genesis 2000 manufactured by Orbotech Inc. of Tustin, Calif., GerbTool V13 manufactured by WISE Software Solutions, Inc. of Newberg, Oreg., CAM350 V8.0 manufactured by DownStream Technologies of Bolton, Mass. or CAM Master V8.4.50 manufactured by Pentalogix of Walnut Creek, Calif. Other CAM editing software can be also used. The initial design can then be modified to accommodate the presence of one or more electrically conductive constraining cores. The construction of a printed wiring board in this manner is discussed in greater detail with reference to FIG. 15. In other embodiments, custom software can be created using the inventive principles described herein to automate the design of printed wiring boards that include electrically conductive constraining cores in a manner that does not involve creating a design for a printed wiring board that does not account for the presence of electrically conductive constraining cores with the printed wiring board.

A process for constructing a printed wiring board in accordance with an embodiment of the method of the present invention is shown in FIG. 15. The process (450) involves obtaining (452) Gerber data for the basic printed wiring board design using conventional design software. Gerber data typically includes information concerning the configuration of any signal layers, ground plane layers, power plane layers, split plane layers, any reference plane layers and/or mix planes. In addition, the Gerber data can include fab drawings, drill data, solder mask layers and silk screen layers. The Gerber data can be edited (454), which involves adjusting trace widths, adjusting the size of annular rings, adjusting clearance pad sizes, compensating for drill size for the copper plating, checking for design rule violations and accommodating manufacturing equipment precision. As part of the editing process, the Gerber data is used to identify where clearance holes should be located within the electrically conductive constraining cores. If the electrically conductive constraining cores are not functional layers, then a clearance hole can be allocated for each of the plated through holes. For embodiments where the electrically conductive constraining core acts as a functional layer of the printed wiring board, the Gerber data includes artwork for the functional layer implemented by the electrically conductive constraining core. The artwork indicates the plated through holes that form electrical connections with the functional layer. Clearance holes can be associated with each plated through hole that does not form an electrical connection with the functional layer. The locations of the clearance holes are then used to generate (456) clearance hole drill data for drilling the electrically conductive constraining cores.

As discussed above, an analysis of the clearance hole drill data is performed to identify if clearance holes are overlapping. If clearance holes are overlapping, then the two holes are converted to a channel either by adding additional drilling locations or by using a router to create a slot. Any additional drilling and/or routing information is then added (458) to the electrically conductive constraining core drill data.

Similarly, adjacent clearance holes that are determined to be too close to each other are converted to channels either by drilling additional holes or routing a slot. In one embodiment, a threshold distance of 1 mil is used when the clearance holes have a diameter of 25 mil. In other embodiments, thresholds of 4 mil, 5 mil or 6 mil are used for similarly sized clearance holes. The threshold can often depends on the size of the hole and the manufacturing yield desired. The amount of the threshold can also depend upon whether the electrically conductive constraining core base material is clad or unclad, because the cladding can provide additional support. The additional drill holes and/or routing information is then added (460) to the electrically conductive constraining core drill data.

If the board includes cut outs, inserts, electrically isolated edges or electrically isolated regions (such as in a split-plane functional layer), then pre-fab data can be generated (462) to co-ordinate the necessary pre-fab processes required to implement these features. The pre-fab processes that can be used to implement each of these features are discussed above.

Having completed the generation of the drill data and pre-fab data, artwork for patterning the clad surfaces of the electrically conductive constraining cores can be generated (464). In one embodiment, artwork can be generated (466) by masking all of the electrically conductive constraining core except for the regions that are to be drilled or routed to form channels (including channels routed as part of pre-fab processes). All of the features copied to the artwork are reduced (468) by an amount to reduce etching of the cladding away from the edges of the routed feature. In several embodiments where a 25 mil drill is used, the features are often reduced by at least 5 mil. In other embodiments the features are reduced by at least 10 mil and in further embodiments the features are reduced by at least 15 mil. Typically, the features are reduced by between 8 mil to 12 mil when a 25 mil drill is used. Once the features are reduced, a negative is taken to produce the artwork. In addition to the features, the artwork may include a boundary around the edges of the electrically conductive constraining cores to etch the cladding away from the edges.

Panelization (470) can be used when manufacturing multiple printed wiring boards simultaneously in accordance with an embodiment of the present invention. Panelization simply involves copying the drill data, pre-fab data and artwork multiple times to reflect the number of printed wiring boards being constructed from the panel.

Following panelization, registration targets can be added (472) to all of the panelized layers of the printed wiring board including the artwork of the electrically conductive constraining cores. Holes at target locations can also be added (474) to the drill data for the constraining core.

Scaling factors can be applied to the artwork, drill data and prefab data of the electrically conductive constraining core in order to accommodate for the expansion or contraction of the electrically conductive constraining core during manufacture of a printed wiring board. Typically, the scaling factor depends upon the materials used in the construction of the electrically conductive constraining core and can be impacted by the location on a panel from which the electrically conductive constraining core is to be manufactured. In one embodiment where the electrically conductive constraining core is constructed from PAN carbon fiber T300-3k-199gsm plain weave woven carbon fabric composite manufactured by Cytec Carbon Fiber LLC of Greenville, S.C., a scaling factor 0.65 mil/inch is used in the short direction of the panel and a scaling factor of 0.90 mil/inch is used in the long direction of the panel. In another embodiment where the electrically conductive constraining core is constructed from PITCH carbon fiber CN80-1.5k-195gsm plain weave fabric composite manufactured by Nippon Graphite of Japan, the same scaling factors can be used. The appropriate scaling factors for other materials can be obtained by observing the expansion or contraction of the materials during standardized manufacturing processes.

In one embodiment, the artwork layers are scaled (476) with the exception that the registration targets are not scaled. In addition, the drill data and pre-fab data for the electrically conductive constraining core can also be modified by a scaling factor. Again, the locations of the registration holes are not scaled.

Upon completion of the generation of the data necessary for the construction of the electrically conductive constraining cores, the data can be exported to the various machines that are used to print, etch and drill printed wiring board materials. The machines and the data can then be used to construct materials that can be laminated and drilled to form a completed printed wiring board in accordance with several aspects of the present invention.

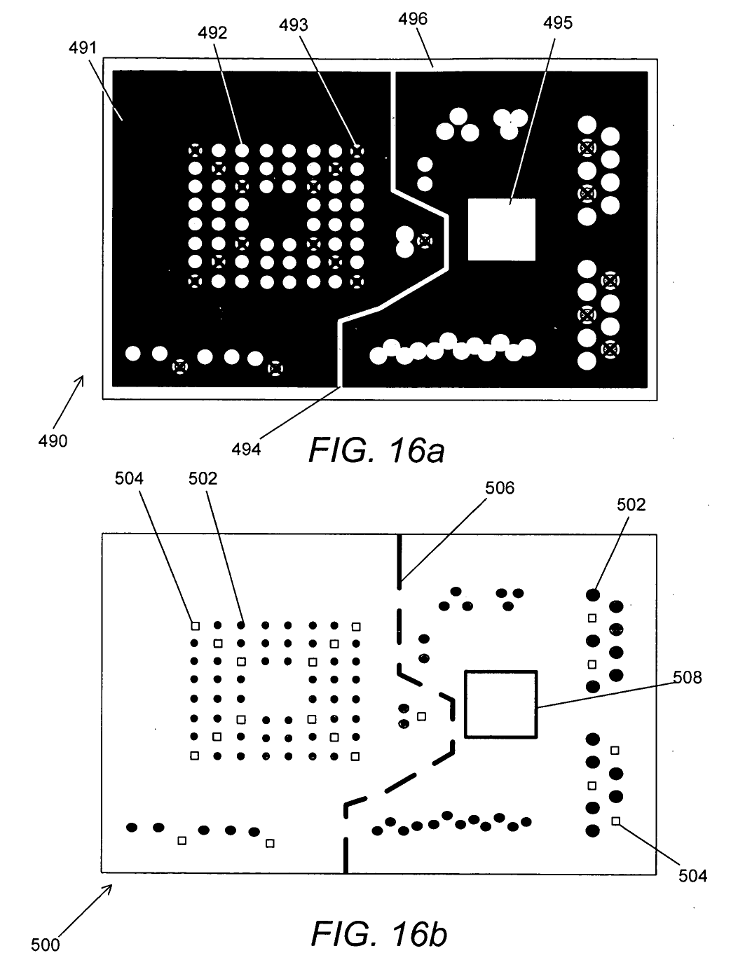

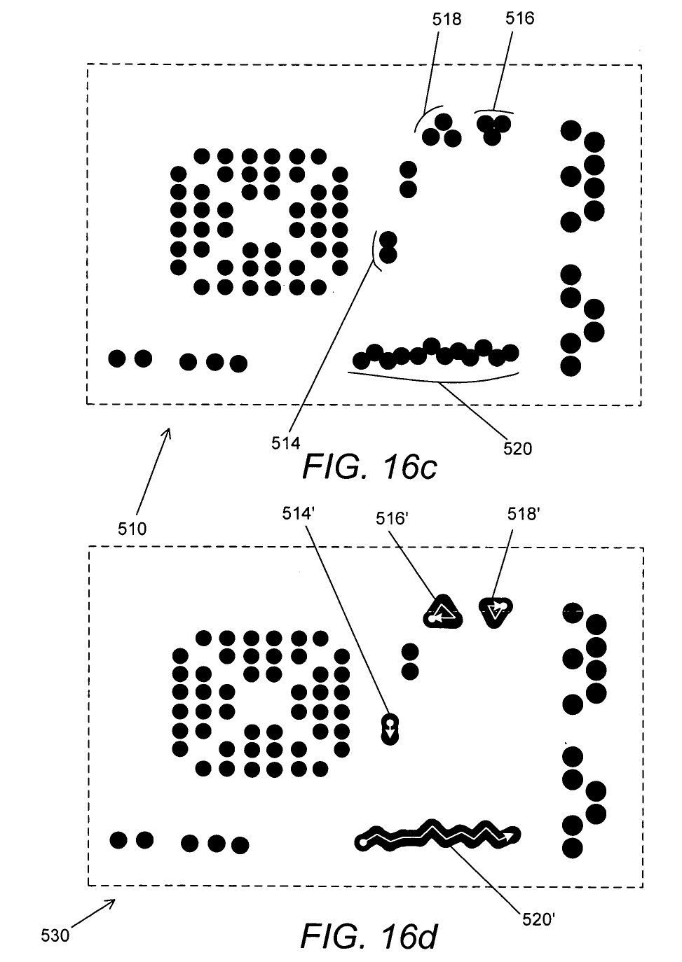

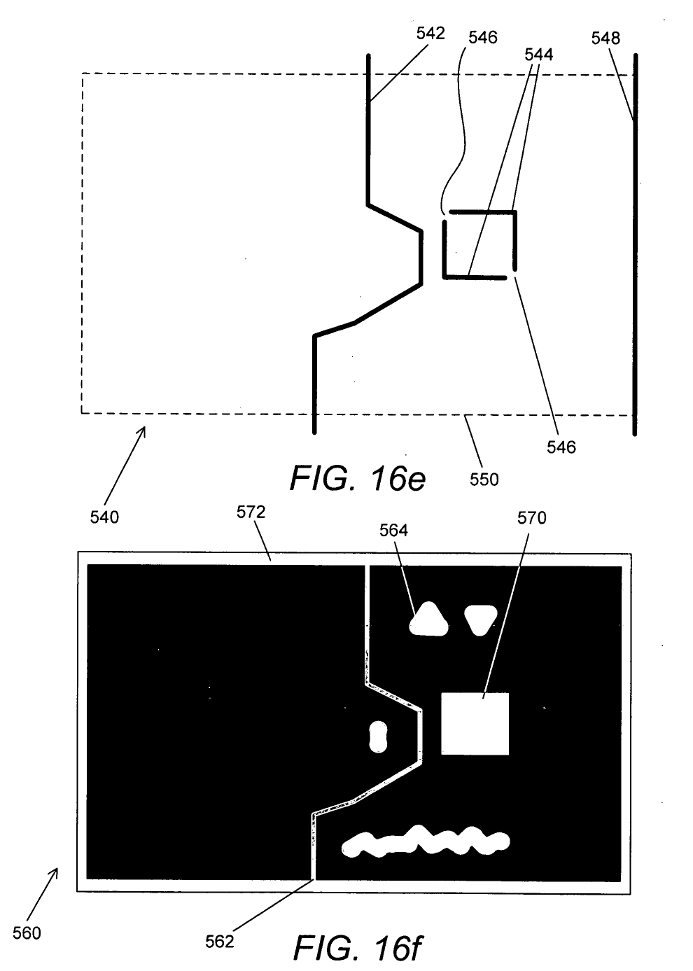

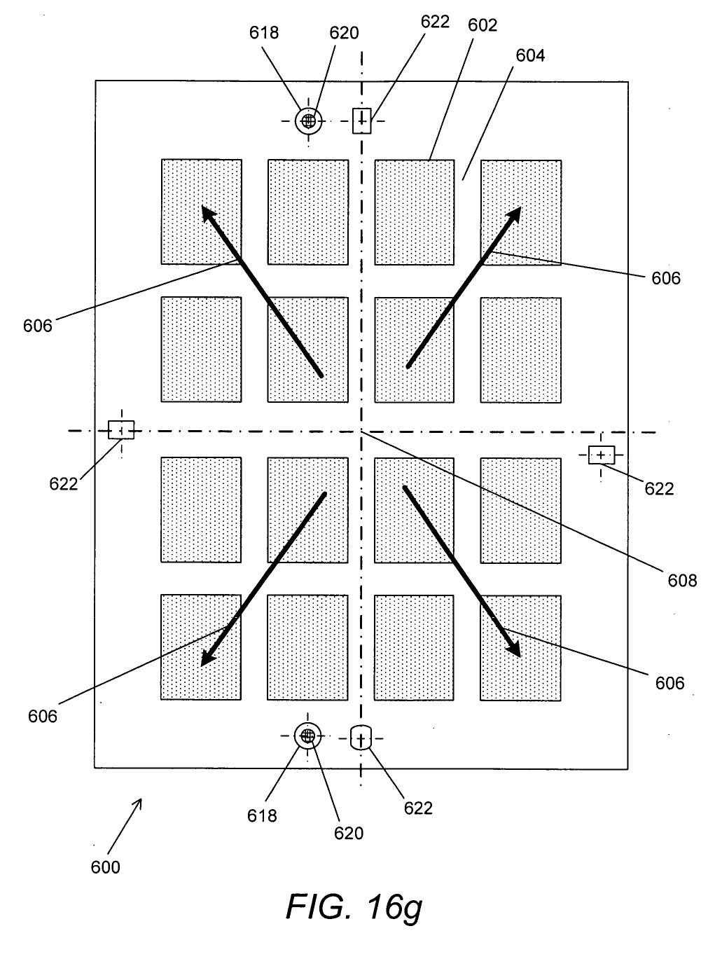

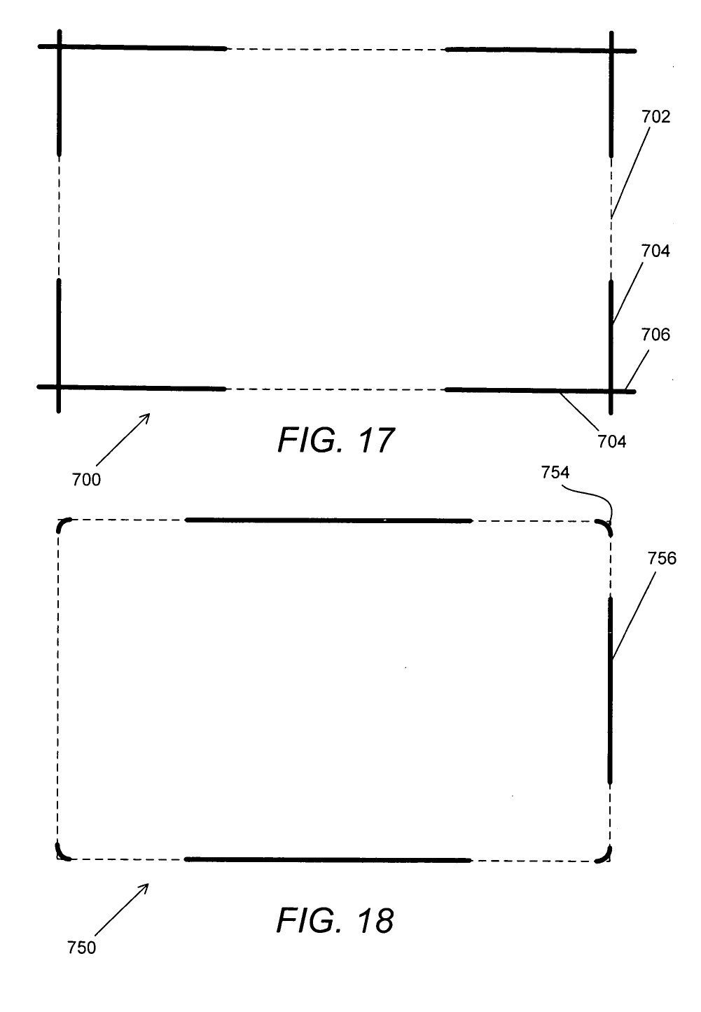

The process illustrated in FIG. 15 can be understood with reference to FIGS. 16a-16d. Gerber data for a split ground and power plane of a printed wiring board is illustrated graphically in FIGS. 16a and 16b. A graphical representation of artwork for a functional layer of the printed wiring board is shown in FIG. 16a. The artwork 490 includes masked regions 491 and exposed regions. The exposed regions include pads 492 through which plated through holes can pass, while maintaining electrical isolation from the functional layer. The thermal patterns 493 that can be constructed in association with plated through holes that connect with the functional layer are also exposed. In addition, the artwork exposes a region 494 that divides the plane and a region 495 that ultimately forms a cut out.

FIG. 16b shows a graphical representation of Gerber through hole drill data. The Gerber data 500 indicates the location of a number of different sized plated through holes 502 that are electrically isolated from the split plane. Plated through holes that are intended to be electrically connected to the split plane are indicated by squares 504. A ghost line 506 demarcates the boundary between the ground and power planes of the split plane. A cut out region 508 is also indicated.

Drill data and artwork can be obtained from the Gerber data to enable the implementation of the split ground and power plane design on an electrically conductive constraining core. Drill data for the electrically conductive constraining core can be generated in accordance with the methods described above. The drill data generated from the Gerber data shown in FIGS. 16a and 16b is represented graphically in FIG. 16c. The drill data for the electrically conductive constraining core is initially generated by placing a clearance hole in the location of each plated through hole that is not intended to make electrical connections with the split plane. As discussed above, the clearance holes are typically placed in the same location as the plated through hole with a diameter that is greater than that of the plated through hole. The diameter of the clearance hole is typically scaled to create sufficient electrical isolation between the electrically conductive constraining core and the plated through hole. The size of the diameter can be impacted by the type of resin and the signals within the printed wiring board, when operational.

Once the clearance hole data is generated, the clearance hole data is inspected to identify adjacent clearance holes that are overlapping or located within a predetermined distance of each other. A pair of clearance holes 514 overlaps. Therefore, the drill data is modified to replace these clearance holes with a channel. As discussed above, the channel can be generated using additional drill holes or by routing a slot. A trio of clearance holes 516 also overlaps. The drill data is also modified to replace these three holes with a channel. Another trio of holes 518 are located within a minimum distance threshold and, therefore, the drill data can be modified to replace these holes with a channel. In addition, a large group of clearance holes 520 overlap each other. As with the other overlapping clearance holes, the drill data is modified to replace the clearance holes with an appropriate channel.

A graphical representation showing drill data derived by modifying the drill data shown in FIG. 16c to replace overlapping clearance holes and clearance holes that violate a minimum distance threshold with channels is shown in FIG. 16d. In the illustrated embodiment, each of the channels is to be generated using a slot drill tool. The pair of clearance holes 514 is replaced by the slot 514′. The trios of clearance holes 516 and 518 are replaced with the slots 516′ and 518′ respectively. The large group of clearance holes 520 is replaced with the slot 520′. In each instance, the path described by a slot drill creating the slot is indicated by an arrow.

Pre-fab data including channels associated with the pre-fab of the electrically conductive constraining core is illustrated graphically in FIG. 16e. The pre-fab data 540 includes several channels. A first channel 542 is a slot following the boundary demarcating the ground plane portion and the power plane portion of the split plane. A pair of channels 544 are included in the pre-fab data. The channels 544 electrically isolate the majority of the edges of the electrically conductive constraining core exposed following the removal of a cut out region. Small tabs 546 remain. As described above, these tabs ensure that the region, which is to be cut out, remains in position during lamination. The pre-fab data includes another channel 548. This channel is designed to enable the electrical isolation of an edge of the electrically conductive constraining core. The channels 542 and 548 extend beyond the boundaries of the electrically conductive constraining core, which are indicated by ghost lines 550. As discussed above, extending the channels a distance beyond the boundaries of the electrically conductive constraining core ensures that resin can extend along the entire length of the edge that is being electrically isolated.

As discussed above, artwork for the electrically conductive constraining cores can be generated by copying the resin filled channels from the drill data and the pre-fab data, reducing these features and creating a negative. Typically, an exposed perimeter is also added to the artwork. Artwork including an exposed perimeter generated from the drill data shown in FIG. 16d and the pre-fab data shown in FIG. 16e is graphically represented in FIG. 16f. The artwork 560 includes an exposed channel 562 that follows the line dividing the power and ground planes of the electrically conductive constraining core. The artwork also includes exposed regions 564 corresponding to the channels that electrically isolate plated through holes. In addition, the artwork includes an exposed region 570 that corresponds to the region that will be cut out of the electrically conductive constraining core during the manufacture of a printed wiring board. As mentioned previously, the artwork also exposes the edges 572 of the electrically conductive constraining core.

The panelization of the drilling and artwork data can be understood with reference to FIG. 16g, which shows the location of a number of electrically conductive constraining cores on a panel. The panel 600 includes 16 regions 602 corresponding to regions in which individual electrically conductive constraining cores are to be drilled, printed and etched. During the processing of the panel, the materials in the panel can expand and/or contract in directions 606 radiating from the center 608 of the panel. Therefore, the drill data, prefab data and the artwork associated with each electrically conductive constraining core on the panel can be scaled according to the material of the panel and the particular constraining cores location within the panel.

The panelization also involves determining the locations of post etch registration targets. Many conventional post etch punch machines, such as the range of machines manufactured by Multiline Technologies of Farmingdale, N.Y., rely on the transparency of dielectric material to locate registration targets. Essentially, these machines locate registration targets by searching for a shadow within a specified region. The material of the electrically conductive constraining core is typically not light transparent. Therefore, drilling a hole enables the location of registration targets by using similar machines that are configured to search for light within the predetermined region. Once the target is located, post etch punch holes 622 can be made in the panel. In many embodiment, the diameter of the registration hole is between 26 mil and 32 mil. In other embodiments, the diameter of the registration hole can be the same diameter as a target pad.

Once the drill data, pre-fab data and artwork for the electrically conductive constraining cores is finalized the data can be exported to appropriate manufacturing machinery. Panels of electrically conductive constraining core base material can then be processed as described above and used to form printed wiring boards in accordance with the method of the invention.

The techniques above can be applied to any variety of designs. In addition to the pre-fab processes described above, examples of other pre-fab processes that can be performed are described below. A variety of pre-fab steps can be performed to electrically isolate regions of an electrically conductive constraining core. Pre-fab data for the creation of channels that can electrically isolate corners of an electrically conductive constraining core is represented graphically in FIGS. 17 and 18. Referring first to FIG. 17, pre-fab data for a region in a panel 700 of electrically conductive constraining core base material is shown. The boundary of an electrically conductive constraining core that is to be manufactured from the panel is shown as ghost lines 702. Pairs of perpendicular channels 704 intersect at the each corner of the electrically conductive constraining core. A portion 706 of each channel extends beyond the point at which the channels intersect to ensure that resin can completely fill the channels at the point of intersection.

Another embodiment of pre-fab data in accordance with the present invention is illustrated graphically in FIG. 18. Pre-fab data for a region in a panel 750 of electrically conductive constraining core base material is shown. The boundary of an electrically conductive constraining core that is to be manufactured from the panel is shown as ghost lines 752. The pre-fab data includes channels 754 routed in small arcs at the corners of the electrically conductive constraining core. Additional channels 756 run along lengths of the edges of the electrically conductive constraining core.

The pre-fab data shown in FIGS. 17 and 18 can be used to construct printed wiring boards in accordance with embodiments of the method of the present invention that have electrically conductive constraining cores with electrically isolated corners. In other embodiments, other configurations of channels can be manufactured during pre-fab processes to electrically isolate lengths along edges and/or corners of electrically conductive constraining cores.

Although the foregoing embodiments are disclosed as typical, it would be understood that additional variations, substitutions and modifications can be made to the system, as disclosed, without departing form the scope of the invention. For example almost an infinite array of drilling and pre-fab routing processes can be performed to provide electrically conductive constraining cores in any manner of configuration. In addition, drilling, slot drilling and routing have been described above for creating channels, however, mechanical punching, high pressure water jet cutting and laser cutting can also be used to create channels. In addition, although the description above refers to the manufacture of printed wiring boards the same techniques can be used to manufacture substrates. Accordingly, the scope of the invention should be determined not by the embodiments illustrated, but by the appended claims and their equivalents.

1. A printed wiring board, comprising an electrically conductive constraining core including a resin filled channel.

2. The printed wiring board of claim 1, further comprising:
a plurality of plated through holes;
wherein at least two of the plurality of plated through holes pass through the resin filled channel.

3. The printed wiring board of claim 2, wherein:
the channel is a number of overlapping holes filled with resin; and
the number of overlapping holes is greater than the number of plated through holes passing through the channel.

4. The printed wiring board of claim 1, wherein:
the electrically conductive constraining core includes an edge;
the resin filled channel electrically isolates the electrically conductive constraining core from objects that only contact the electrically conductive constraining core at points along the length of the edge.

5. The printed wiring board of claim 1, wherein the channel divides the electrically conductive constraining core into electrically isolated regions.

6. The printed wiring board of claim 1, wherein:
the channel defines a region within the electrically conductive constraining core; and
the materials of the region defined by the channel have physical properties that differ from at least one other region of the electrically conductive constraining core.

7. A printed wiring board, comprising an electrically conductive constraining core including a channel filled with a material having a dielectric constant less than or equal to 6.0 at 1 MHz.

8. The printed wiring board of claim 1, further comprising:
a plurality of plated through holes;
wherein at least two of the plurality of plated through holes pass through the filled channel.

9. The printed wiring board of claim 2, wherein:
the channel is a number of overlapping holes filled with a material having a dielectric constant less than or equal to 6.0 at 1 MHz; and
the number of overlapping holes is greater than the number of plated through holes passing through the channel.

10. A method of constructing a printed wiring board, comprising:
forming an electrically conductive constraining core base material;
forming at least one channel in the electrically conductive constraining core base material;
laminating a stack-up including the electrically conductive constraining core base material to enable resin to flow into the at least one channel;
drilling holes through the laminated stack-up; and
plating the linings of the drilled holes with electrically conductive material.

11. The method of claim 10, wherein at least one channel is formed in a location such that at least two of the drilled holes extend through the channel.

12. The method of claim 10, wherein at least one channel is formed in a location such that at least a length of an edge of the electrically conductive constraining core base material is electrically isolated from objects that only contact the laminated stack-up at locations along the length of the edge.

13. The method of claim 10, wherein at least one channel is located to electrically isolate one portion of the electrically conductive constraining core base material and another portion.

14. A method of constructing a printed wiring board comprising:
obtaining Gerber data;
generating drill data for an electrically conductive constraining core, where the drill data includes at least one channel; and
generating artwork for an electrically conductive constraining core.

15. A method of building a printed wiring board having a predetermined number of plated through holes that are electrically isolated from an electrically conductive constraining core within the printed wiring board, comprising drilling a number of clearance holes in an electrically conductive constraining core that is greater than the predetermined number of plated through holes that are electrically isolated from the electrically conductive constraining core.

16. The method of claim 11, further comprising:
laminating a stack-up including the clearance hole drilled electrically conductive constraining core; and
drilling the plated through holes that are electrically isolated from the electrically conductive constraining core through the laminated stack-up.

17. The method of claim 12, further comprising drilling plated through holes that are electrically connected to the electrically conductive constraining core.

18. A printed wiring board, comprising:
a plurality of layers that are electrically isolated from each other;
means for constraining the printed wiring board;
means for transmitting signals between the plurality of layers;
means for electrically isolating at least part of the means for transmitting signals from the means for constraining the printed wiring board.
